(19) United States
(12) Patent Application Publication
(10) Pub. No.: US 2024/0311674 A1
(43) Pub. Date: Sep. 19, 2024

(54) QUANTUM STATE STABILIZATION BY QUANTUM COUPLING

(71) Applicant: The Regents of the University of California, Oakland, CA (US)

(72) Inventors: Michael Scheibner, Merced, CA (US); Mark Woodall, Merced, CA (US)

(21) Appl. No.: 18/571,165

(22) PCT Filed: Jun. 15, 2022
(86) PCT No.: PCT/US2022/033672

§ 371 Date: Dec. 15, 2023

Related U.S. Application Data
(60) Provisional application No. 63/211,206, filed on Jun. 16, 2021.

(51) Int. Cl. G06N 10/40

(52) U.S. Cl. CPC G06N 10/40

(57) ABSTRACT

Generally discussed herein are techniques for and systems and apparatuses configured to reduce susceptibility to charge noise. A device can include electrical contacts, an atom-like system situated to interact with a first electrical field provided through the electrical contacts and produce a second electrical field responsive to the first electrical field, and an atom-like structure situated to interact with the first electrical field and the second electrical field, such that the atom-like structure is less sensitive to charge noise in the device.

### CLAIM OF PRIORITY

This application claims the benefit of priority to U.S. Patent Application Ser. No. 63/211,206, filed on Jun. 16, 2021, which is incorporated by reference herein in its entirety.

### GOVERNMENT RIGHTS

This invention was made with government support under Grant No. HDTRA1-15-1-0011 awarded by the Defense Threat Reduction Agency. The government has certain rights in the invention.

### BACKGROUND

There have been different strategies to stabilizing quantum states against charge noise. These can be classified into two categories, (1) suppression of the sources of charge noise and (2) suppression of the sensitivity to charge noise.

Suppression of the sources of charge noise can involve working with ultra-clean materials such as group III-V semiconductor materials fabricated with molecular beam epitaxy. Even the highest purity group III-V semiconductor quantum dot (QD) structures have defect states that cause charge noise to which quantum states embedded in these materials are susceptible (see for example: Houel, et al. Physical Review Letters 108, 107401 (2012), Kuhlmann, et al. Nature Physics 9, 570-575 (2013), and Kumar, et al. Phys. Rev. B 102, 085423 (2020)).

To suppress sensitivity to charge noise one can choose the route of more strongly confined atom-like systems in solid-state materials, such as atomic defects in 2D-van der Waals materials, nitrogen-vacancy centers or silicon atom dangling bond states (these are at times called single atom quantum dots). Nonetheless, these systems still possess sensitivity to charge noise. Another approach to desensitize the quantum states is to intentionally saturate the (defect) sites at which charges randomly localize with charges and/or work in specific frequency ranges (see Kuhlmann, et al. Nature Physics 9, 570-575 (2013)). Optical feedback mechanisms have also been used to frequency stabilize the optical emission from (single) solid state qubits (Prechtel et al. Physical Review X 3, 041006 (2013)). In pairs of QDs, so called coupled QDs or QD molecules (QDMs), stabilization against charge noise has thus far been performed by symmetrically biasing the particular states between two charge state resonances (Hunter, et al. Physical Review Letters 116, 110402 (2016), Martins, et al. Physical Review Letters 116, 116801 (2016), Carter, et al. Nano Letters 19, 6166-6172 (2019)). Often this is done as part of stabilizing spin states.

It is desired to better control and reduce the susceptibility of atom-like structures, i.e., the quantum states they host, to charge noise.

### BRIEF DESCRIPTION OF DRAWINGS

Various ones of the appended drawings illustrate embodiments of the subject matter presented herein. The appended drawings are provided to allow a person of ordinary skill in the art to understand the concepts disclosed herein, and therefore cannot be considered as limiting a scope of the disclosed subject matter.

FIG. 1 illustrates, by way of example, a diagram of an embodiment of a system with reduced sensitivity to charge noise of a device.

FIG. 2 illustrates, by way of example, a diagram of an embodiment of a system for reducing sensitivity of the first coupled atom-like structure and the second coupled atom-like structure to charge noise of a crystal host matrix.

FIG. 3 illustrates by way of example, two quantum dot molecules separated by a distance, r, and each occupied by an indirect exciton |iX>, a state in which the electron and hole that form the exciton occupy different quantum dots.

FIG. 4 illustrates, by way of example, two quantum dot molecules separated by a distance, r, with one occupied by an indirect exciton the other by a molecular superposition state of a direct and indirect exciton, |iX>(+/−)|X>.

FIG. 5 illustrates, by way of example, a diagram of a graph of electric field dispersed energy levels versus applied electric field strength (Fₑₓₜ) of excitons in two neighboring quantum dot molecules.

FIG. 6 is an exploded view diagram of a portion of the graph in FIG. 5 that shows a signature braid pattern (an “S-shape” and “Z-shape” line crossing) caused by tunneling of a charge in a coupled quantum dot molecule.

FIG. 7 is an exploded view diagram of a portion of the graph in FIG. 5 that shows another signature braid pattern caused by tunneling of a charge in a coupled quantum dot molecule.

FIG. 8 illustrates, by way of example, a graph of the z-component of an electric dipole field, F_{z}, of an indirect exciton between two QD layers as a function of QDM separation.

FIG. 9 illustrates, by way of example, a graph of the energy of an indirect exciton in quantum dot molecule 2 versus applied electric field that is the s-shaped branch of a braid pattern for a variety of tunnel coupling energies of a charge of an exciton in quantum dot molecule 1.

FIG. 10 illustrates, by way of example, a graph of the energy of an indirect exciton in quantum dot molecule 2 (QDM-II) versus applied electric field (Fₑₓₜ) that is the s-shaped branch of a braid pattern for a variety of quantum dot molecule separations, r.

FIGS. 11A, 11B, 11C, and 11D illustrate, by way of example, graphs of simulated electric field dispersed energy spectra of an S-shaped branch of an indirect exciton transition of quantum dot molecule 1 (QDM-I) while an exciton undergoes a hole tunnel resonance in QDM-II.

FIG. 11E illustrate a graph of spectra at select applied electric fields around the saddle point shown in FIG. 11B that illustrates the progression between Gaussian and Lorentzian line shape.

FIGS. 11F and 11G illustrate, by way of example, graphs of minimally achievable fluctuation-induced energy variation of the indirect exciton state with the described stabilization mechanism
(ΔE^{S}) divided by fluctuation-induced energy variation of the indirect exciton without the described stabilization mechanism
(ΔE^{iX}) versus tunnel coupling energy for various materials with different dielectric constants, ϵᵣ.

FIG. 12A illustrates, by way of example, a graph of electric field dispersed Eigen energies of the neutral exciton in QDM-II around its hole tunneling resonance. Optically active (solid lines) and optically inactive states (dashed lines) are shown.

FIG. 12B illustrates, by way of example, a graph of simulated optical PL transitions of the exciton states shown in 12A. Only PL transitions from optically active states are shown.

FIG. 13A illustrates, by way of example, a graph of electric field dispersed Eigen energies of the neutral exciton in QDM-I around the electric field at which QDM-II exhibits its hole tunneling resonance that is shown in FIG. 12A. Only optically active excitons states are shown for the exciton in QDM-I.

FIG. 13B illustrates, by way of example, a graph of simulated optical PL transitions of the exciton states shown in 13A. Only PL transitions from optically active states are shown.

FIGS. 14A, 14B, 14C, 14D, and 14E illustrate, by way of example, respective graphs of signatures in the braid patterns of an indirect exciton in QDM-I revealing spin fine structure around the corresponding tunneling resonances of different charge states in QDM-II a neutral exciton, a neutral biexciton, a positive trion, a single hole, and two holes, FIGS. 14F, 14G, 14H, 14I, and 14J, respectively.

FIGS. 14A, 14B, 14C, 14D, and 14E together with FIGS. 14F, 14G, 14H, 14I, and 14J illustrate that the (excitonic) charge state in one QDM functions as a remote sensor for the charge and spin states in a neighboring QDM.

FIG. 15 illustrates, by way of example, a diagram of an embodiment of a method for device operation with reduced sensitivity to noise.

### DETAILED DESCRIPTION

The description that follows includes illustrative apparatuses, systems, methods, and techniques that embody various aspects of the subject matter described herein. In the following description, for purposes of explanation, numerous specific details are set forth to provide an understanding of various embodiments of the subject matter. It will be evident, however, to those skilled in the art that embodiments of the subject matter may be practiced without at least some of these specific details.

This disclosure relates generally to the field of controlling charge noise susceptibility of atom-like structures. Embodiments use a quantum mechanical tunnel resonance of a quantum state in a second pair of coupled atom-like quantum structures to stabilize the frequency of a quantum state in a first (pair of coupled) atom-like quantum structure(s). Instead of avoiding the tunnel resonances and/or states that straddle two (or more) of the atom-like quantum structures, embodiments can use the tunnel resonances to stabilize the eigen-frequency of quantum states. Embodiments can do this process either to states that straddle two or more atom-like quantum structures, or to states in a single atom-like quantum structure. Embodiments also allow stabilization to be performed in a highly targeted fashion applied to a specific neighboring system rather than on a less local scale as for example in Kuhlmann (2013), which is limited by the optical diffraction limit. Embodiments do not rely on an active feedback mechanism. However, embodiments can be combined with other stabilization techniques to further enhance the stabilization.

Reducing sensitivity of atom-like quantum systems to fluctuating charges in a solid-state device structure has been addressed in various ways. In coupled quantum dot systems specifically, it has been approached by symmetrically biasing the system, such that a flat point in the energy dispersion between two tunnel resonances of the system under consideration is established. This situation cannot be achieved for arbitrary charge states and charge configurations though. Other approaches include the intentional saturation of defect sites that host the fluctuating charges or adding additional dopant layers. These approaches provide limited control and affect a large area of the device structure. Optical feedback mechanisms have been used to actively compensate for fluctuations. These by their nature require constant measurement of the system. Device approaches for frequency standards based on quantum systems have been using many quantum systems.

The frequency stabilization process of embodiments can include a precision operation. A specific nanometer or sub-nanometer scale quantum system can be stabilized controllably. This can be done by tuning an (externally) applied electric field. The precision arises from the fact that the atom-like quantum systems allow for control of the location of a single electronic charge on a (sub-)nanometer or even atomic scale. A wide variety of charge (and spin) configurations can be realized for frequency stabilization, providing a large device design flexibility. Embodiments can be used to stabilize electronic states, optical transitions, and spin-states in these atom-like quantum structures.

Using a second system to stabilize the states in a first system provides much more flexibility to use the first system. By carefully designing (or operating) the second (control) system, stabilization can be accomplished at the desired configuration of the first system (target system). For coupled atom-like quantum emitters, this allows to stabilize spatially indirect transitions, something that has not been achieved before. The stabilization of the spatially indirect optical transitions allows for the development of even more precise frequency standards and sensors, because the spatially indirect states can be designed to have very long lifetimes, which translates via the Heisenberg uncertainty principle to very narrow spectral transitions.

Embodiments can also be used as to sense the quantum states in the second atom-like quantum system. Each charge and spin state in the second quantum system creates a response in the first quantum system that is characteristic of the charge and spin configuration in the second quantum system.

Embodiments can provide an ability to stabilize quantum states in atom-like quantum systems against charge noise, making them suitable as qubits for quantum computers and other quantum information processing devices. Embodiments can provide a local quantum sensor that can sense the charge and spin state of a nearby quantum system, thereby acting as a readout. A device fabricated in accord with embodiments can be used as a logical switch, by making a charge tunnel in the one system, as its energy is shifted by an electronic or excitonic state in the other system. Thereby, an optical transition can be turned on/off. Embodiments can provide stabilization against charge noise that can be utilized to build frequency standards. Depending on the particular system used this frequency standard can be realized for a wide range of desired frequencies. Devices build in accord with embodiments can provide stabilization against charge noise and can be used to build sensors, such as magnetometers and accelerometers.

Embodiments enable commercial semiconductor based quantum technology because it overcomes a major obstacle of such technology, namely the charge noise instability, for using solid-state quantum systems for quantum computers and other quantum technology. Because embodiments can be implemented with a large variety of atom-like solid state quantum systems (as mentioned above), including systems that work at room temperature (or require only moderate cooling), commercial use can be fairly imminent.

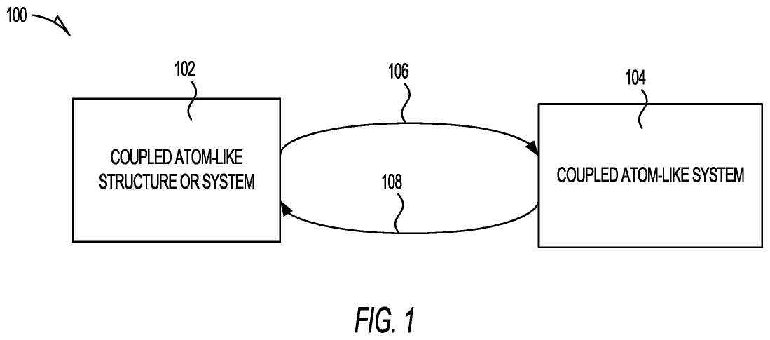

FIG. 1 illustrates, by way of example, a diagram of an embodiment of a system 100 with reduced sensitivity to charge noise of a device. The system 100 as illustrated includes a coupled atom-like structure or system 102 and a coupled atom-like system 104. A first electric field 106 emanating from the coupled atom-like structure or system 102 can be incident on the coupled atom-like system 104. Likewise, a second electric field 108 emanating from the coupled atom-like system 104 can be incident on the coupled atom-like structure or system 102. The first electric field 106 and the second electric field 108 can be modelled as Coulomb interactions between the coupled atom-like structure or system 102 and the coupled atom-like system 104. The first electric field 106 and the second electric field 108 are not necessarily equal and opposite as an external electric field incident on the coupled atom-like structure or system 102 and the coupled atom-like system 104 can be different and the constituents (e.g., electron(s), hole(s), or devoid) of the coupled atom-like structure or system 102 and the coupled atom-like system 104 can be different as well.

An atom-like structure is a structure that harbors zero-dimensional quantum states. Such a structure can be a quantum dot, Nitrogen-vacancy Center, silicon atom dangling bond single atom quantum dot, strain-induced dots, atomic defects, or the like. An atom-like structure that is tunnel-coupled to another atom-like structure is called a coupled atom-like structure.

An atom-like structure system includes one, two, or more atom-like quantum structures that are coupled via quantum mechanical tunnel coupling. A system comprised of two or more tunnel-coupled atom-like structures is called a molecular system. A quantum dot molecule (QDM) is an example of a molecular system.

An energy dispersion control system of embodiments can include an atom-like structure system tunnel coupled to an atom-like structure or an atom-like structure system. The control system can include a molecular system, such as a quantum dot molecule or multiple atom-like quantum structures. The target system (the one that is to be controlled) can be a single atom-like quantum structure, such as a single quantum dot, or an atom-like structure system.

The coupled atom-like structure or system 102 and the coupled atom-like system 104 can both include quantum dot molecules, nitrogen vacancy centers in diamond, silicon atom dangling bond single atom quantum dots, or strain-induced quantum dots in two-dimensional van der Waals materials. The discussion focuses on the coupled atom-like structure or system 102 and the second atom-like structure both including quantum dots, but the discussion is easily generalized to apply to nitrogen vacancy centers in diamond, silicon atom dangling bond single atom quantum dots, or strain-induced quantum dots in two-dimensional van der Waals materials, other atom-like quantum structures, or a combination thereof.

Nitrogen vacancy centers in diamond are respective point defects in diamond. A nitrogen vacancy center exhibits photoluminescence, which allows an observer to read out the spin-state of the nitrogen vacancy center optically. The electron spin of the nitrogen vacancy center, localized at atomic scales, can be manipulated at room temperature by external factors such as magnetic, or electric fields, microwave radiation, or light, resulting in sharp resonances in the intensity of the photoluminescence. These resonances can be explained in terms of electron spin related phenomena such as quantum entanglement, spin-orbit interaction and Rabi oscillations, and analyzed using advanced quantum optics theory. An individual NV center can be used as a basic unit for a quantum computer, a qubit, or the like.

A dangling bond is an unsatisfied valence on an immobilized atom. An atom with a dangling bond is also referred to as an immobilized free radical or an immobilized radical. Some allotropes of silicon, such as amorphous silicon, display a high concentration of dangling bonds. Besides being of fundamental interest as atom-like structures, these dangling bonds are important in modern semiconductor device operation and are also of interest because they are promising candidates for maintaining their quantum properties up to room temperature. Thus, dangling bonds are potential building blocks for room temperature quantum devices.

Van der Waals materials are made up of strongly bonded two-dimensional (2D) layers that are bound in the third dimension through weaker dispersion forces. Graphite is an example of a Van der Waals material.

A quantum dot molecule is a pair of quantum dots that exhibit quantum tunneling. A quantum dot is a man-made nanoscale crystal that can confine an electron (and/or hole) in all three spatial dimensions.

Quantum dots (QDs) and quantum dot molecules (QDMs) are model systems for studying quantum phenomena and developing quantum based technologies for quantum information processing, sensing, and metrology, among other phenomena. Inspired by the atomic clock, the latter technologies seek to improve the sensitivity and precision of classical sensors by orders of magnitude. Measurement sensitivity and precision are directly connected to the sharpness of the signal that is being monitored to measure a physical quantity. The sharpness of the signal, in turn, is connected to the longevity of the monitored quantum state. While physical systems with long lifetimes and coherence times can be conceived fairly easily, the more sensitive such a physical system becomes, the more susceptible it will be to noise in its environment, or even within itself, as is the case with QDMs and other solid state quantum systems. For the purpose of description and without loss of generality, QDMs herein are pairs of two InAs/GaAs QDs, vertically stacked in growth direction and embedded in a field-effect structure that allows applying a homogeneous electric field along the growth direction (axis of the QDM). The typical sizes of the QDs range from about 5 nm to 20 nm laterally, and from 2 nm to 5 nm vertically. Typical dot densities range from 10¹¹ cm⁻² to 10⁸ cm⁻², equivalent to an average lateral separation between QDMs of about 30 nm to 1 μm, respectively.

Such QDMs can host two distinct species of optical excitations, short-lived (˜1 ns) spatially direct electron-hole (e-h) pairs (electron and hole in the same dot) and long-lived (≈10 ns-100 us and longer) spatially indirect excitons (electron and hole in separate dots). The indirect excitons can be interesting for sensing. The spatial separation and resulting reduced wave function overlap of electron and hole of the indirect exciton, which can be designed in the QDM fabrication via properties of the barrier between the dots, result in various favorable features: First, the much reduced wave function overlap causes a longer lifetime, Δt, and promises a narrower spectral linewidth via the Heisenberg uncertainty principle (ΔEΔt≥h/2). Second, the indirect exciton occupies a larger volume than the direct exciton, resulting in higher sensitivity to changes in the crystal structure, such as strain due to external forces. Third, electron and hole of the indirect exciton form a much larger electric dipole than in the direct exciton case, as the dipole moment \vec{p}=\vec{d}q is defined as the product of charge, q, and charge separation, \vec{d}, which makes the indirect exciton sensitive to and tunable by electric fields. Consequently, the increased sensitivity also results in higher sensitivity to noise, such as random charge fluctuations within the crystal and device structure. For example, the spectral linewidth of the indirect exciton, contrary to what is expected from the Heisenberg uncertainty principle, is found to be about ten times larger rather than 10 times (or more) smaller than that of the direct exciton. (T. Nakaoka et al., Direct observation of acoustic phonon mediated relaxation between coupled exciton states in a single quantum dot molecule, Physical Review B—Condensed Matter and Materials Physics 74, 1 (2006)). This broadening has been ascribed to charge fluctuations at, both, defects in the crystal structure as well as at interfaces in the device structure.

Just as well as these random charge fluctuations influence the charge states in the QDMs, the charge states in the QDMs may influence charges in their vicinity, including those in nearby QDMs. In contrast to the random charge fluctuations at defect sites and interfaces, the charge states in the QDMs are highly controllable. Embodiments show how a non-linear response of charge states in QDMs to externally applied electric fields at tunneling resonances can be utilized to tailor the sensitivity of a nearby QDM's charge states to electric fields.

This discussion is applicable to the other atom-like structures mentioned herein.

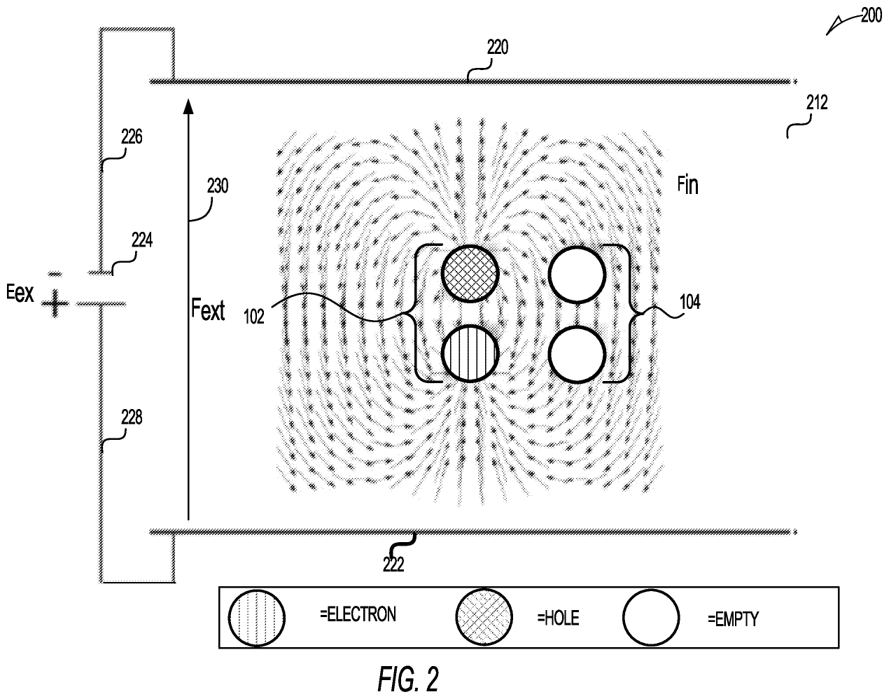

FIG. 2 illustrates, by way of example, a diagram of an embodiment of a system 200 for reducing sensitivity of the coupled atom-like structure or system 102 and the coupled atom-like system 104 to charge noise of a crystal host matrix 212. The system 200 includes the coupled atom-like structure or system 102 and the coupled atom-like system 104 embedded in a crystal host matrix 212. The system 200 further includes a first electrical contact 220 and a second electrical contact 222 electrically connected to a power supply 224 via interconnects 226, 228, respectively. 220 and 222 form a capacitor that allows to generate an electric field between them (external electric field). FIG. 2 illustrates that if a pair of coupled 0-dimensional quantum structures is charged, as for example here with an electron in one (vertical stripes) and a hole (cross-hatch) in the other quantum structure of a pair, the charges create an electric field that extends into the vicinity adding to the external field at the location of a neighboring pair of coupled 0-D quantum structures. The total electric field at the position of the second pair is the sum of the externally applied field and the internal field generated by the charges in the first pair of coupled 0-D quantum structures.

The crystal host matrix 212 can include a semiconductor that includes positively or negatively doped, undoped, or intrinsic silicon, germanium, carbon, or a combination thereof. The crystal host matrix 212 can include a compound that includes a compound that is a semiconductor, such as indium arsenide (a compound including indium and arsenic), gallium arsenide (a compound including gallium and arsenic), cadmium selenide, zinc selenide, or other compound semiconductor material. The crystal host matrix 212 can include cadmium, indium, gallium, nitrogen, phosphorus, antimony, selenium, tellurium, oxygen, sulfur, graphene, diamond, glass, oxide, chlorine, titanium, lead, manganese, nickel, iron, chromium, silicon, silver, platinum, iodine, thallium, bromine, or a combination thereof. The crystal host matrix 212 can include other semiconductor materials, such as a metal compound including multiple of the additives discussed. Note that an insulator (e.g., dielectric), such as glass, oxide, transition metal dichalcogenides, van-der Waals materials, or diamond, can be used in place of or in conjunction with the crystal host matrix 212.

The contact 220, 222 or interconnect 226, 228 can include a material such as a metal, semiconductor, or other electrically conductive material.

The system 200 can include a gating mechanism through which an electric bias can be applied to the crystal host matrix 212. The gating mechanism shown in FIG. 2 includes two electrically conductive contacts 220, 222 coupled to the power supply 224. In one or more embodiments, an electrical potential bias can be applied directly to the contact 220, 222 rather than applying the bias to the interconnect 226. 228.

A quantum dot can include materials similar to or the same as crystal host matrix 212. In an embodiment where the coupled atom-like structure or system 102 and the second coupled atom-like structure includes a nitrogen vacancy center, the crystal host matrix 212 can be diamond.

A quantum dot can be on the order of tens of nanometers or less. A quantum dot is a semiconductor that has zero or more charges confined in all three spatial dimensions (i.e. length, width, and height), comparable to the extension of the wave function/deBroglie wavelength of the charge, thus, the quantum dot is a zero-dimensional structure. A quantum dot is a nanocrystal, typically including a semiconductor material. A quantum dot is configured to exhibit quantum mechanical properties.

The coupled atom-like structure or system 102 and the coupled atom-like system 104 can be separated by a distance that is dependent on material used to form the atom-like structures of the atom-like structure or atom-like system, material used to form the crystal host matrix, orientation of the atom-like structure or system relative to the atom-like system (e.g., whether they are horizontally separated (as shown in the FIGS.) vertically separated, or the like), geometry of the atom-like structure or atom-like system, or the like.

In the side-by-side configuration, the zero-dimensional coupled atom-like structure or system 102 and the coupled atom-like system 104 can be placed with a high precision using a site controlled growth technique. In the vertical configuration, the zero-dimensional coupled atom-like structure or system 102 and the coupled atom-like system 104 can be placed with a high precision using self-assembly.

The system 200 illustrates an internal electric field, Fin, that is produced by an indirect exciton in the coupled atom-like structure or system 102. An indirect exciton includes an electron in a first quantum dot of a quantum dot molecule and a hole in a second quantum dot of the quantum dot molecule. To simplify the illustration and without loss of generality, the second atom-like structure is left empty here.

An externally applied electric field, \vec{F}ₑₓₜ, from the power supply 224 shifts the energy of the exciton according to ΔE=−\vec{p}\vec{F}ₑₓₜ, which reduces to ΔE=−p\vec{F}ₑₓₜ as both are considered to be aligned along a first quantum dot molecule axis 230. The externally applied electric field enables electron or hole energy level resonances between two quantum dots at which quantum tunneling mixes the direct and the indirect exciton. The properties of this mixed state are correspondingly averaged. The dipole moment at these resonances changes continuously from that of the indirect to that of the direct exciton or vice versa. For the sake of simplicity and without loss of generality, the dipole moment of the direct exciton is set to zero for the following simulations. The matrix form of the Hamiltonian describing a ground state exciton in such a QDM reads as Equation 1:

$$H = ( \begin{matrix}{E}_{X}^{0} & - t \\ - t & {E}_{iX}^{0} - p {F}_{ext}\end{matrix} ) \qquad Equation 1$$

Here t is the tunnel coupling energy, E_{X}⁰ and E_{iX}⁰ denote the band gap energies of the direct and the indirect exciton at zero applied electric field, respectively. This Hamiltonian describes the restricted case of either the electron or the hole tunneling while the other charge remains localized in one dot. The Hamiltonian also neglects spin interactions, whose effects will be introduced and discussed below. Quantum dot molecules with a center-to-center dot separation of d=10 nm are considered. The quantum dot molecules are considered to exhibit hole tunneling while the electron remains fixed in the bottom dot, yielding p=+1 meV/(kV/cm) for the indirect exciton. The resulting Eigen energies of the Hamiltonian as a function of electric field are hyperbolas with an energy separation of 2t at their vertex and asymptotes that are given by the matrix elements on the Hamiltonian's main diagonal matrix elements.

The Coulomb interactions between laterally adjacent quantum dot molecules (e.g., first and second coupled atom-like quantum structures 102, 104) are typically neglected when constructing the multiparticle Hamiltonian; however, at sufficiently small separations, the effect will become significant. The electric dipole of the indirect exciton creates an electric field itself that extends into its vicinity. In the equatorial plane a distance r=|\vec{r}| away from the indirect exciton, its dipole field measures as in Equation 2:

$${\vec{F}}_{e h} ( r , {F}_{e h} ) = \frac{1}{4 {πϵ}_{0} {ϵ}_{r}} \frac{- \vec{p} ( {F}_{e x t} )}{{r}^{3}} = k \frac{- \vec{p} ( {F}_{e x t} )}{{r}^{3}} \qquad Equation 2$$

Here ϵ₀ is the vacuum dielectric constant and ϵᵣ is the relative permittivity of the crystal matrix. ϵᵣ=12.9 for GaAs. Note, this dipole field of the exciton depends on the externally applied field. The dipole field changes as the exciton changes from indirect to direct (or vice versa) at a tunneling resonance.

An exciton in a quantum dot molecule (QDM-I) that is sufficiently close to a neighboring quantum dot molecule (QDM-II) containing an indirect exciton will react to the additional electric field, and its energy levels will adjust accordingly. The Hamiltonian from Equation 2 then changes to Equation 3:

$$H = ( \begin{matrix}{E}_{X}^{0} & - t \\ - t & {E}_{iX}^{0} - p ( {F}_{ext} + {F}_{eh , z} )\end{matrix} ) \qquad Equation 3$$

The externally applied electric field, Fₑₓₜ, is combined with the local electric field from the dipole of the exciton in QDM-II F_{eh,z} (oriented along the growth direction, z) and applied to the dipole moment, p. Likewise, the energy levels of the exciton in QDM-II will adjust because of the field of the exciton in QDM-I. This results in an energy shift in the electric field dispersed optical response proportional to F_{eh,z}, as well as characteristic braiding features corresponding to the locations of the avoided crossing of the indirect exciton of the neighboring quantum dot molecule with its direct exciton state.

Instead of describing the interaction between the excitons in the two quantum dot molecules (e.g., first and second coupled atom-like quantum structures 102, 104) in terms of local electric fields, a description in terms of Coulomb potentials provides an approach that allows taking into account the position of the individual charges more easily. In this approach, the Hamiltonian for the exciton in QDM-I, while an exciton is present in QDM-II can be described as in Equation 4:

$$H = ( \begin{matrix}{E}_{X}^{0} & - t \\ - t & {E}_{iX}^{0} - p {F}_{ext} + ( \frac{k}{r} - \frac{k}{\sqrt{{r}^{2} + {( {S}_{t} [ {F}_{e x t} + β ] d )}^{2}}} )\end{matrix} ) \qquad Equation 4$$

The function, Sₜ[Fₑₓₜ+β] describes the transition between direct and indirect exciton in QDM-II. Here, due to the choice of dot separation, r in FIG. 3, Sₜ[Fₑₓₜ+β] is the absolute value of the slope of the i-th Eigen energy function of the exciton Hamiltonian of QDM-II. This takes into account the effect that the exciton in QDM-I has on the exciton in QDM-II, by adding the field term

$$β = 2 k / p ( \frac{1}{r} - \frac{1}{\sqrt{{r}^{2} + {d}^{2}}} )$$

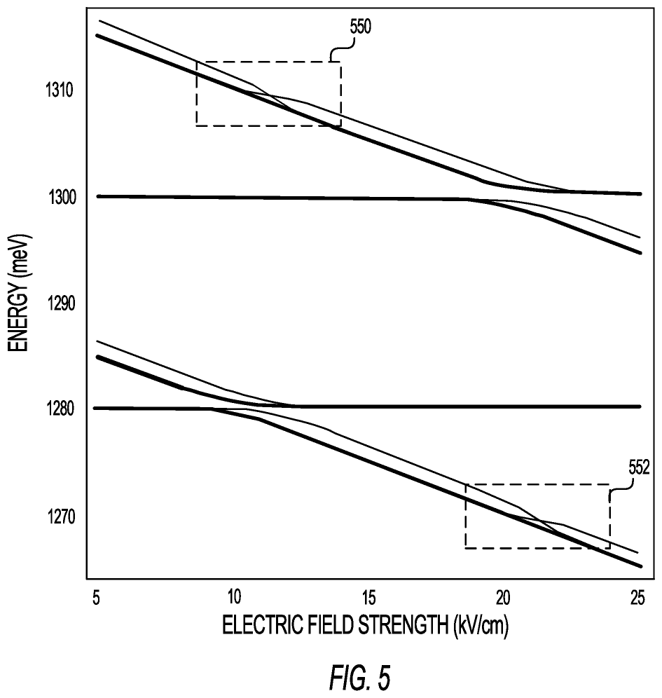

to the applied field in its argument. The resulting Eigen energy functions of the excitons of two quantum dot molecules are illustrated in FIGS. 5, 6, and 7.

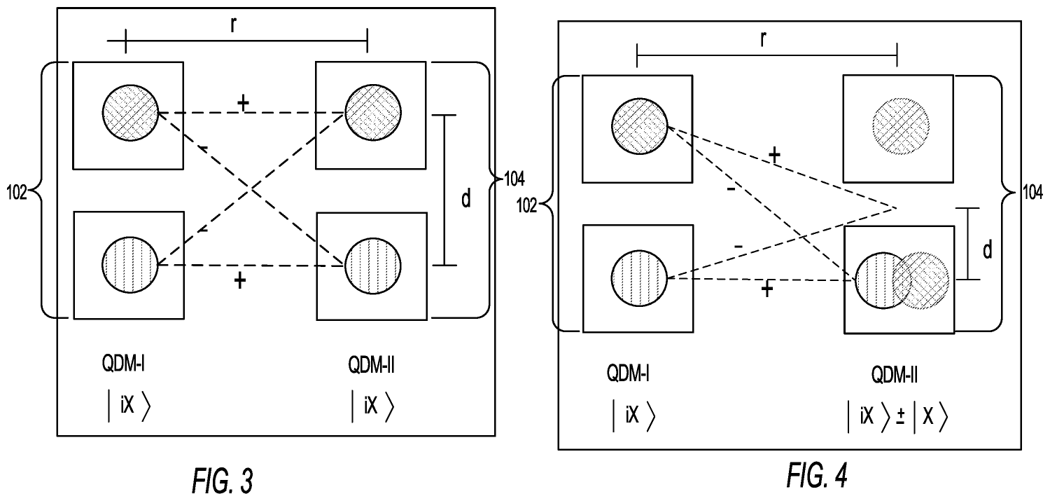

FIG. 3 illustrates, by way of example, two quantum dot molecules (e.g., the atom-like structure or system 102, and the atom-like system 104) separated by a distance, r, and each occupied by an indirect exciton |iX>. FIG. 4 illustrates, by way of example, two quantum dot molecules (e.g., first and second coupled atom-like quantum structures 102, 104) separated by a distance, r, with one occupied by an indirect exciton the other by a molecular superposition state of a direct and indirect exciton, |iX>(+/−)|iX>. The separation, \tilde{d}, between electron and hole in an indirect exciton equals the center-to-center dot separation in a QDM, d. For the state, |X>(+/−)|iX>, the electron-hole separation is effectively \tilde{d}=d/2.

FIG. 5 illustrates, by way of example, a diagram of a graph of exciton eigen energy versus applied electric field strength (Fₑₓₜ). FIG. 5 shows simulated electric field dispersed eigen energies of the neutral excitons of two quantum dot molecules (QDMs) in a vicinity of their ground state hole tunnel resonances, without (thick lines) and with (thin lines) dipole-dipole interaction. The two QDMs were simulated with tunnel coupling energies of t_{I}=1.0 meV (QDM with higher energy exciton) and t_{II}=0.5 meV (QDM with lower energy exciton). A QDM separation of r=20 nm was used.

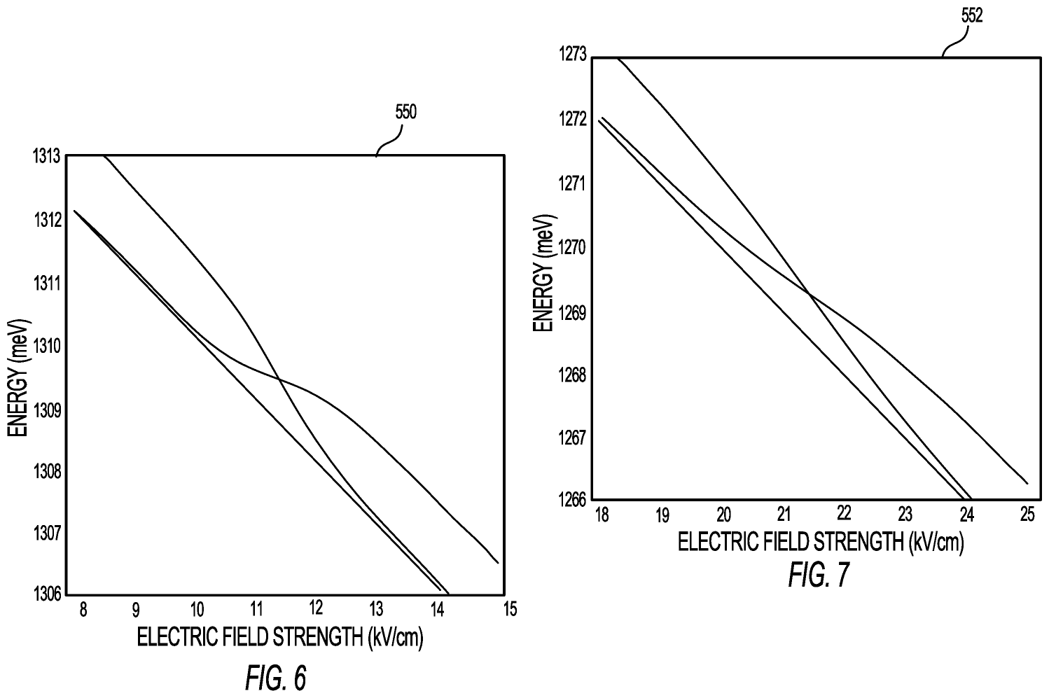

FIG. 6 is an exploded view diagram of a portion of the graph in FIG. 5 that shows a signature braid pattern 550. FIG. 7 is an exploded view diagram of a portion of the graph in FIG. 5 that shows another signature braid pattern 552.

As the recombination of the excitons is a statistical process, with one or the other exciton randomly recombining first, photoluminescence (PL) measurements reveal an electric field dispersed energy level structure as shown in FIG. 6, if the Coulomb interactions are sufficiently strong. The indirect exciton states and transitions form a characteristic “braid-like” pattern, at the applied electric field at which the other quantum dot molecules undergoes a tunnel resonance. The close-ups of the braid-like patterns in FIGS. 6 and 7 indicate that the magnitude of the tunnel coupling in the other quantum dot molecule determines the curvature of the “S-shaped” and “Z-shaped” branches of the braid.

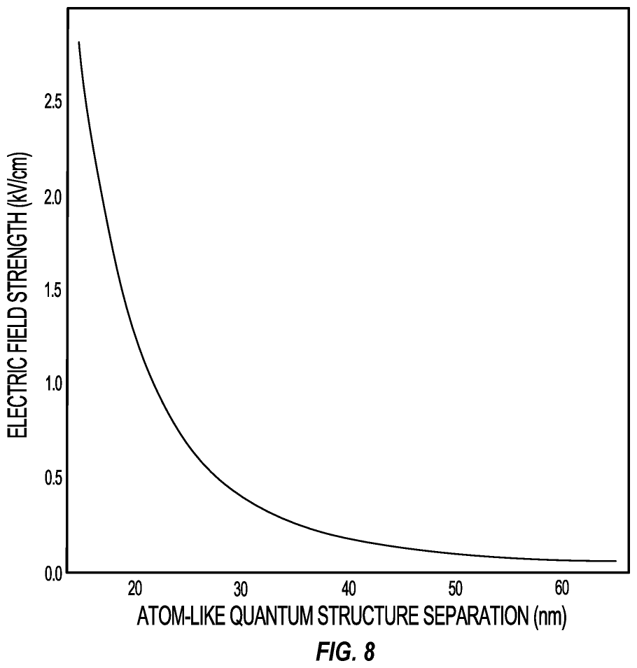

FIG. 8 illustrates, by way of example, a graph of the z-component of an electric dipole field, F_{z}, between two QD layers as a function of QDM separation. As can be seen, the electric dipole field, F_{z}, decreases as QDM separation, r in FIG. 3, increases.

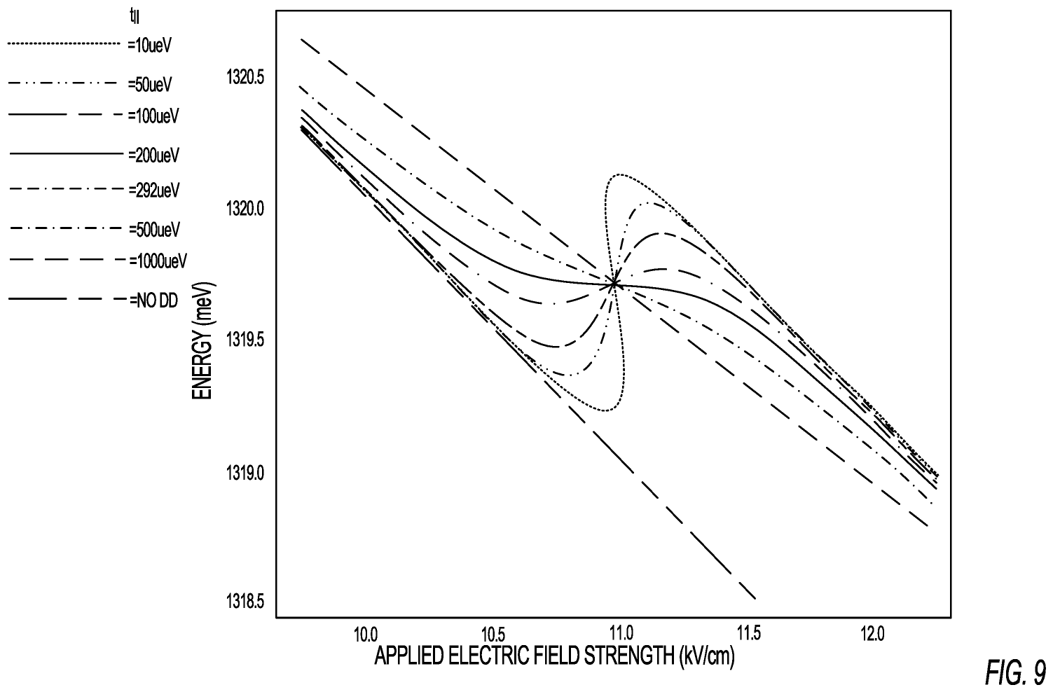

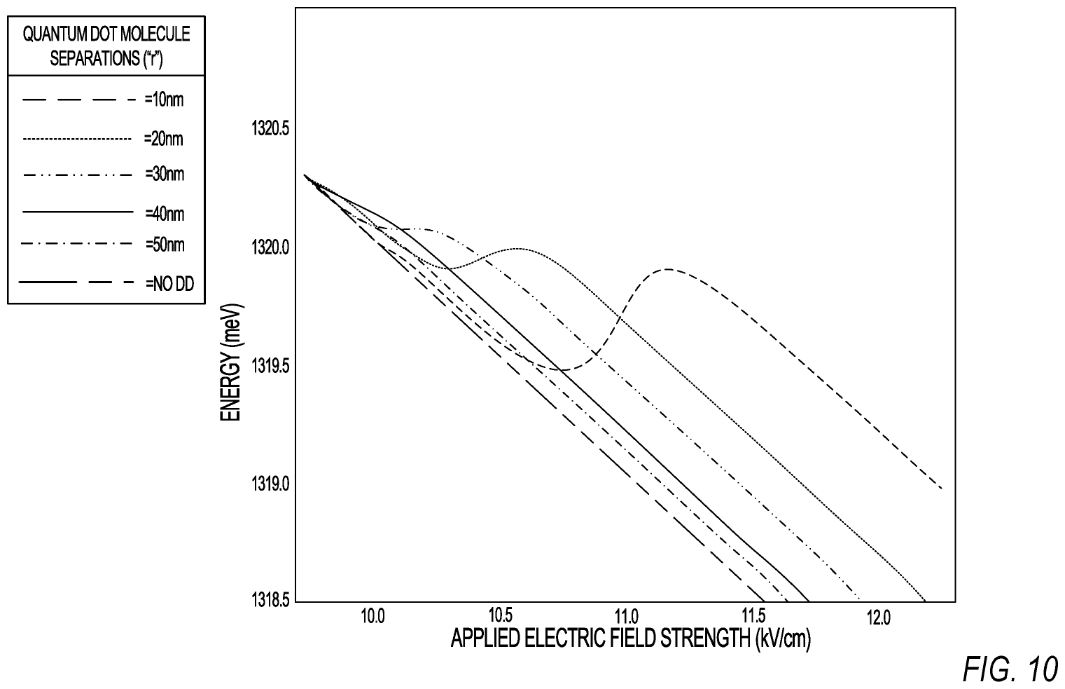

The curvature of an “S-branch” in one quantum dot molecule can be controlled via a tunnel resonance in a neighboring quantum dot molecule. This is illustrated in FIGS. 9 and 10.

FIG. 9 illustrates, by way of example, a graph of QDM-I's (indirect) exciton eigen energy versus applied electric field for a variety of tunnel coupling energies of the exciton in QDM-II. FIG. 9 shows how the curvature of the S-branch of the braid-like pattern of the indirect exciton in QDM-I changes with the tunnel coupling strength, t_{II}, of the exciton in QDM-II. The simulated electric field dispersed eigen energy of the S-shaped branch of the indirect exciton of QDM-I while an exciton in QDM-II undergoes a tunnel resonance is illustrated as function of the tunnel coupling energy, t_{II}. As t_{II} decreases, the slope of the center of the S-branch increases, becoming more and more positive. In the limit t_{II}→0—that is, the transition from indirect to direct exciton in QDM-II becomes abrupt with applied electric field—the slope approaches positive infinity.

FIG. 10 illustrates, by way of example, a graph of indirect exciton eigen energy (S-shaped branch) versus applied electric field (Fₑₓₜ) for a variety of quantum dot molecule separations, r. FIG. 10 shows how the curvature of the S-branch of the braid of the indirect exciton in QDM-I changes with the separation, r, between both quantum dot molecules. The simulated electric field dispersed eigen energies of the S-shaped branch of the indirect exciton of QDM-I while an exciton undergoes a tunnel resonance in QDM-II of FIG. 10 is illustrated as function of the QDM separation, r, for t_{II}=100 ueV. Note that there exists a particular condition t_{II}=t̅₂ for which the S-branch forms a saddle point with a zero slope at its center point. For t_{II}<t̅₂ two local extrema exist with an increasingly positive slope in between. The farther apart the two quantum dot molecules, the smaller the Coulomb interaction between both. Consequently, the braid is located closer to the electric field at which QDM-II exhibits its tunnel resonance when QDM-I is empty, the width of the braid becomes narrower and the change in slope the S-branch undergoes gets smaller. In other terms, for larger quantum dot molecule separation, a smaller tunnel coupling is needed to obtain an S-branch with a saddle point in the other quantum dot molecule.

The case for t_{II}=t̅₂ is particularly interesting. At this point, the energy dispersion of the indirect exciton is least dependent on the externally applied electric field. In other words, this condition results in minimal change to the Eigen energy under fluctuating electric fields. Consequently, the optical transition at this point exhibits decreased line width broadening and may even approach its lifetime limited value, depending on the width of the saddle region and the magnitude of fluctuations experienced by the quantum dot molecule. While the latter is largely determined by surrounding crystal structure and excitation conditions, the width and slope of the saddle region are a function of the strength of the Coulomb interaction (given by the separation of the two quantum dot molecules, and relative permittivity of the surrounding material) and the tunnel coupling strength, t_{II} of the neighboring quantum dot molecule (FIG. 9).

Quantum dot molecules can exhibit characteristic braided patterns in their electric field dispersed eigen energies and their optical response caused by Coulomb interactions with other nearby quantum dot molecules. FIGS. 5-7 show the braided patterns 550, 552. These braid patterns 550, 552 provide a means for remotely sensing the charge and spin state of one quantum dot molecule with another. Furthermore, these quantum dot molecule pairs set the basis for remote control of one coupled atom-like system 104 by another quantum dot molecule (e.g., coupled atom-like structure or system 102). These braid patterns 550, 552 can be engineered to yield spatially indirect excitonic transitions that are either insensitive or highly sensitive to electric fields. This feature unlocks a plethora of uses of highly adjustable spatially indirect charge states in applications for quantum sensing, quantum metrology, and quantum information. The universality of the underlying Coulomb interaction makes the described phenomena and enabled processes readily transferable to a broad range of coupled atom-like quantum systems and charge states contained therein.

A plethora of atom-like solid-state quantum structures is being studied intensely for their use as fundamental building blocks for quantum technologies. These structures include systems such as quantum dots (QDs), nitrogen vacancy centers (NV-centers) in diamond, silicon atom dangling bond (DB) single atom QDs, strain-induced QDs in two-dimensional (2D) van der Waals materials, and many more. The usefulness of any solid-state quantum system built with such structures, may it be for, for example, quantum information processing, quantum communication, or quantum sensing, increases with the time longevity of a system's quantum states and their quantum coherences. Consequently, efforts focus on minimizing, avoiding, or eliminating processes causing unintended decoherence or collapse of the wave function of the quantum state. Yet, even in ultrapure materials, such as those fabricated in ultra-high vacuum molecular beam epitaxy systems, random charge noise detrimentally affects the quantum states, constituting a major roadblock for the development of a semiconductor-based quantum technology. Embodiments show how to use quantum mechanical tunnel coupling in a quantum dot molecule (QDM) to stabilize quantum states in a neighboring QDM against random (or non-random) charge noise in the overall crystal device structure. The controlled tunneling of an electronic charge in one QDM causes a non-linearity in the energy dispersion of an (opto-)electronic quantum state in a second QDM, resulting in spots of the energy dispersion at which the quantum state and its optical transitions become insensitive to electric field fluctuations. Embodiments further show that the effect allows remote sensing of the charge and spin configurations of the neighboring QDM. The universality of the underlying Coulomb interaction makes the described phenomena and enabled processes readily transferable to a broad range of coupled atom-like quantum systems. The ability to quantum-engineer the energy dispersion of atom-like solid-state quantum states provides a basis for the development of custom solid-state quantum frequency standards, quantum-enhanced sensors, and semiconductor quantum information processors, among other applications.

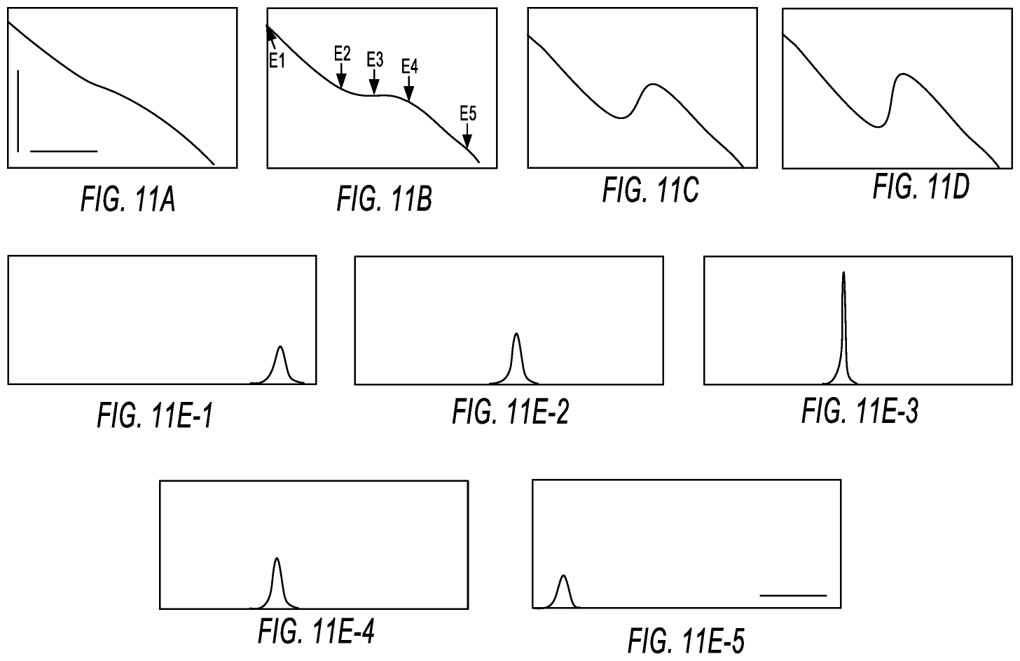

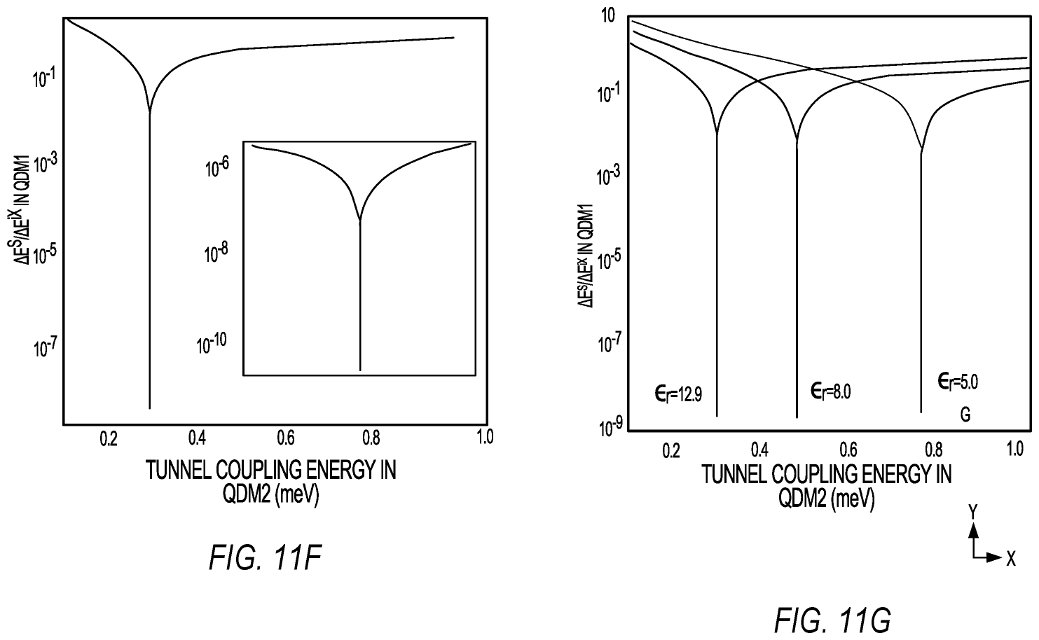

FIGS. 11A-11D illustrate, by way of example, graphs of simulated electric field dispersed PL spectra of the S-shaped branch of the indirect exciton transition of QDM-I while an exciton undergoes a hole tunnel resonance in QDM-II. In FIGS. 11A-11D, the tunnel coupling strength is t₂=500 ueV, t₂=292 ueV, t₂=100 ueV, and t₂=50 ueV, respectively. Scale bars in FIG. 11A indicate 1 meV (vertical) and 1 kV/cm (horizontal).

FIG. 11E illustrates, by way of example, a graph of spectra at select applied electric fields from FIG. 11B. The scale bar indicates 500 ueV.

FIG. 11F illustrates, by way of example, a graph of a change of the energy dispersion of S-shaped branch around the electric field that corresponds to the center of the tunnel resonance in the second QDM. Plotted is the energy difference between points of the S-shaped branch that are off the center by an electric field corresponding to the electric field caused by the crystal structure random charge fluctuations as evidenced by the linewidth of the transition of the indirect exciton away from any braid or anti-crossing. For the simulation, a value of (+/−)50 ueV was used. The obtained energy difference was normalized to the full width at half maximum (FWHM) of an indirect exciton away from any braid or anti-crossing (i.e., here 100 ueV).

FIG. 11G illustrates, by way of example, a graph of a change of the energy dispersion of the S-shaped branch around the electric field that corresponds to the center of the tunnel resonance in the second QDM for three materials with different dielectric constants. The dips seen in FIGS. 11F and 11G) mathematically approach zero. Experimentally, the lowest value is determined by the quantum state's lifetime (natural linewidth) and by how well the tunnel coupling energy in QDM-II can be set.

FIG. 11A, as previously mentioned, illustrates a graph of simulated PL data of the S-shaped indirect exciton transition. The line shape is simulated as a Voigt profile, a convolution of a Lorentzian profile, describing the lifetime limited line width, and a Gaussian profile, describing the fluctuation broadening. The width of the Gaussian profile can be considered a function of the slope of the indirect exciton transition. To calculate the Voigt profile the real part of the Feddeeva function can be used. Equations 5 and 6 describe this function:

$${I}_{P L} ( E , {σ}_{G} , {γ}_{L} ) = ℜ ( \frac{w ( E , {σ}_{G} , {γ}_{L} )}{{σ}_{G} 2 π} ) \qquad Equation 5$$

### With

$$w ( E , {σ}_{G} , {γ}_{L} ) = {e}^{- E - {E}_{i X} + i {γ}_{L /}} {σ}_{G} \sqrt{2} \cdot Erfc ( - i ( E - {E}_{i X} + i {γ}_{L} ) / {σ}_{G} \sqrt{2} ) \qquad Equation 6$$

FIG. 11B illustrates a simulated electric field dispersed PL spectrum of the S-branch obtained with a tunnel coupling energy in QDM-II of t_{II}=292 ueV, which yields a saddle point for the sample parameters used.

FIG. 11E illustrate a graph of spectra at select applied electric fields around the saddle point that illustrates the progression between Gaussian and Lorentzian line shape. At the zero slope point (the part of the line parallel with the x-axis) the line width reduction causes the peak intensity to increase. Note, the total PL intensity of the transition remains constant as the wave function overlap between electron and hole can be assumed not to change significantly if the braid pattern occurs far from a tunnel resonance in this QDM. This simulation illustrates that the shape and the electric field dependence of the line width of the indirect exciton transition can be controlled with another QDM's tunnel resonance via their mutual Coulomb interaction. The interaction can be engineered by adjusting the separation of the QDMs, the relative permittivity, and by designing the potential barrier between the two dots of the QDM to adjust the tunnel coupling strength, t_{II}, of the other QDM. The latter also affects the lifetime of the indirect exciton and hence the lifetime limited linewidth, γ_{L}.

The random charge noise responsible for the Gaussian broadening of the indirect exciton transition away from the flat section remains. To determine the reduction in noise broadening achievable at the flat section, one can measure the energy difference, ΔE^{S}, between two points on the S-shaped branch at applied electric fields that are off the field of the sweet spot by an amount equivalent to half the line width of the single QDM indirect exciton transition, ΔE^{iX}.

FIGS. 11F and 11G illustrate, by way of example, a graph of ΔE^{S}/ΔE^{iX} versus tunnel coupling energy. In FIG. 11F the ratio ΔE^{S}/ΔE^{iX} is shown as a function of the tunnel coupling energy, t_{II}, in QDM-II. At t_{II}=292 ueV a sharp reduction by many orders of magnitude is seen. This strong reduction indicates that, at the substantially horizontal line section, the lifetime limited line widths can be obtained, provided t_{II} can be set with adequate accuracy. Substantially horizontal means that the slope remains less or equal to a slope given by

$${γ}_{L} / ( \frac{Δ {E}^{i X}}{p} )$$

over an electric field range equal to the field of the charge fluctuations,

$$\frac{Δ {E}^{i X}}{p} .$$

The stabilization of the energy dispersion against charge noise persists for materials with different electric permittivity as seen in FIG. 11G.

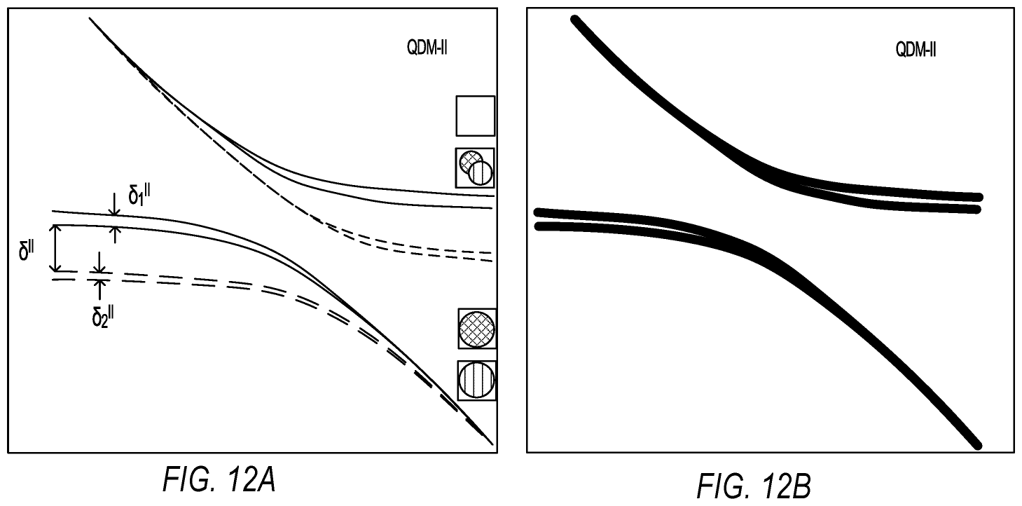

FIG. 12A illustrates, by way of example, a graph of electric field dispersed Eigen energies of the neutral exciton in QDM-II around its hole tunneling resonance. Shown are optically active exciton spin states (solid lines) and optically inactive exciton spin states (dashed lines). The electron-hole exchange energy splitting between the direct exciton spin states are indicated. FIG. 12B illustrates a graph of simulated optical transitions of the exciton states shown in 12A. Only optically allowed transitions are shown.

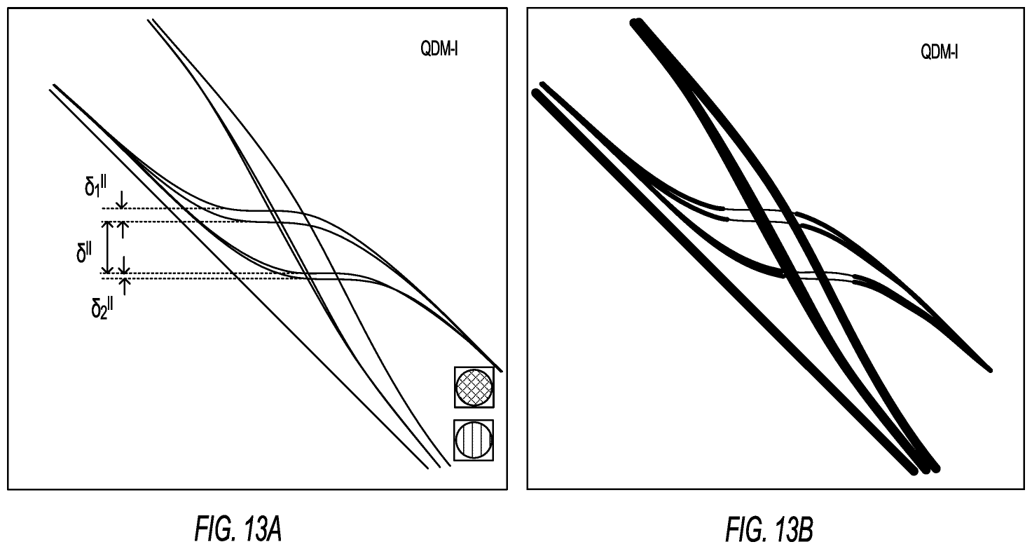

FIGS. 13A, by way of example, a graph of electric field dispersed Eigen energies of the neutral indirect exciton in QDM-I around the applied electric field of a hole tunneling resonance in QDM-II seen in FIG. 12A.

FIG. 13B illustrates, by way of example, a graph of simulated optical transitions of the exciton states shown in 13A. Only optically allowed transitions are shown.

Spin can enter the exciton Hamiltonian via electron-hole spin exchange interactions. The resulting exciton spin fine structure has been studied in detail for single QDs and quantum dot molecules. In quantum dot molecules these spin interactions can manifest themselves as characteristic spin fine structure around tunnel resonances, and via the optical selection rules in the polarization of the optical transitions. To illustrate the effects of the electron-hole spin exchange interaction on the braid pattern it can be sufficient to use a simplified Hamiltonian for the exciton in QDM-II, in which the exchange energy term

$$\begin{matrix}+ \\ ( - )\end{matrix} {δ}^{II} \pm {δ}_{1 ( 2 )}^{II}$$

is added to the Eigen energies of the direct exciton states. Here, δ^{II} signifies the splitting between optically active (bright) and optically inactive (dark) direct exciton states and δ₁₍₂₎^{II} signifies the anisotropic electron hole exchange splitting the bright(dark) direct exciton states. The result is an 8×8 Hamiltonian with 4 sub-Hamiltonians that each take the form of Equation 4. This simplification neglects electron-hole exchange splitting in the indirect exciton states and any mixing of exciton states with different spin, which if introduced would yield a similar energy level structure according to N. Sköld, A. Boyer De La Giroday, A. J. Bennett, I. Farrer, D. A. Ritchie, and A. J. Shields, Electrical control of the exciton fine structure of a quantum dot molecule, Physical Review Letters 110, 1 (2013). For t_{II}=292 ueV (S-branch with saddle point), δ^{II}=200 ueV, δ₁^{II}=40 ueV, and δ₂^{II}=20 ueV, and the exciton Eigen-states in QDM-II exhibit the spin fine structures as shown in FIGS. 13A and 13B. This fine structure will result in the braid pattern of the indirect exciton in QDM-I shown in FIG. 13A. In FIG. 13B, the corresponding optical transition spectrum is simulated. Only the optically bright transitions are shown.

While the optical transitions in QDM-II do not reveal the dark exciton states and their fine structure, the braid pattern in optical transitions of the interdot exciton in QDM-I do. Especially in case of a saddle point in the S-branch of QDM-I indirect exciton, the spin fine structure of the QDM-II exciton is revealed, provided the experimental measurement apparatus provides sufficient resolution and the lifetime limited line width of QDM-I's indirect exciton transitions are sufficiently narrow. The linewidth narrowing around the saddle point would allow to reveal if the electron-hole exchange energies switched signs between direct and indirect excitons. If a finite anisotropic electron hole exchange splitting was also included for the indirect exciton states, all transitions seen in FIG. 13B would split into two transitions. However, the splitting would only be observable around the horizontal line areas of the S-branch.

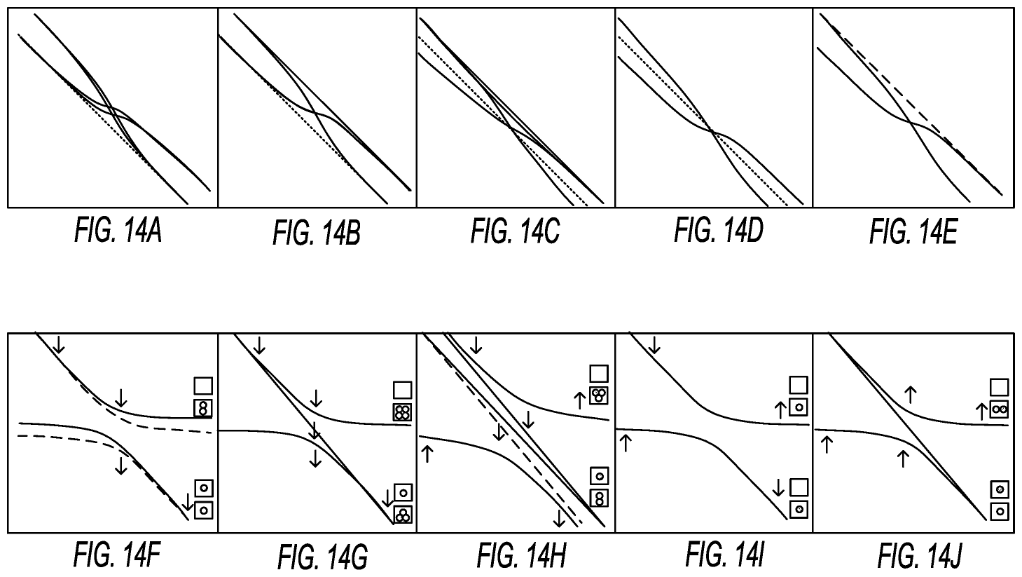

FIGS. 14A, 14B, 14C, 14D, and 14E illustrate, by way of example, respective graphs of signatures in the braid patterns of an indirect exciton in QDM-I revealing spin fine structure around the corresponding tunneling resonance in QDM-II. FIGS. 14F, 14G, 14H, 14I, and 14J in combination with FIG. 14A-14E illustrate that the (excitonic) charge state in one QDM functions as a remote sensor for the charge and spin states in a neighboring QDM. This is, at least in part, because the different charge and spin states exhibit different characteristic patterns, as illustrated in FIG. 14F-14J.

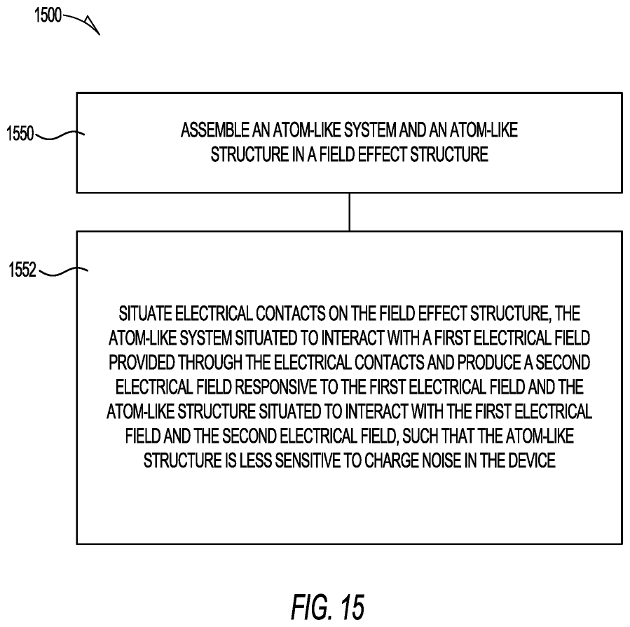

FIG. 15 illustrates, by way of example, a block diagram of an embodiment of a method 1500 for reduced noise sensitivity. The method 1500 as illustrated includes assembling an atom-like system and an atom-like structure in a field effect structure, at operation 1550; situating electrical contacts on the field effect structure, the atom-like system situated to interact with a first electrical field provided through the electrical contacts and produce a second electrical field responsive to the first electrical field and the atom-like structure situated to interact with the first electrical field and the second electrical field, such that the atom-like structure is less sensitive to charge noise in the device, at operation 1552.

The method 1500 can further include, wherein the atom-like system includes a quantum dot molecule, nitrogen vacancy centers in diamond, silicon atom dangling bond single atom quantum dots, strain-induced quantum dots in two-dimensional van der Waals materials, or a combination thereof. The method 1500 can further include, wherein the atom-like system includes a quantum dot molecule, and a quantum tunneling event takes place in the quantum dot molecule.

The method 1500 can further include, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance. The method 1500 can further include, wherein the first electric field is set to a value at which a plot of electric field dispersed eigen energy of the atom-like system versus the first electric field includes a localized substantially horizontal line about the value.

Embodiments provide a mechanism to engineer quantum states in a coupled atom-like solid state quantum system with less susceptibility to noise. Embodiments can use quantum mechanical tunnel coupling of a nearby coupled atom-like solid-state quantum system. The tunnel coupling of charge carriers cause a non-linearity in the energy dispersion of the neighboring system, which can stabilize the quantum state against charge noise. The interaction also enables remote sensing of a systems quantum state, setting the stage for remote control of one quantum system by another. While focus is on the interaction of two neutral excitons herein, the same framework can be applied to other charge and spin states and combinations thereof. Furthermore, because of the dipole nature of the neutral exciton the discussed mechanism suggests it can be transferred to magnetic dipoles. Physical implementation with single spin magnetic dipoles can include much smaller separations between the atom-like quantum systems, which can be accomplished with atomic defects in 2D van der Waals materials, Nitrogen vacancy centers in diamond, or Silicon dangling bond single atom QDs, among others.

### Additional Notes and Examples

One or more aspects of the disclosure may be understood through one or more Example embodiments.

Example 1 can include or use subject matter (such as an apparatus including a processor configured to perform acts, a method, a means for performing acts, or a device readable memory including instructions that, when performed by the device, can cause the device to perform acts), such as can include or use electrical contacts, an atom-like system situated to interact with a first electrical field provided through the electrical contacts and produce a second electrical field responsive to the first electrical field, and an atom-like structure situated to interact with the first electrical field and the second electrical field, such that the atom-like structure is less sensitive to charge noise in the device.

Example 2 can include or use, or can optionally be combined with the subject matter of Example 1, to include or use, wherein the atom-like system includes a quantum dot molecule, nitrogen vacancy centers in diamond, silicon atom dangling bond single atom quantum dots, strain-induced quantum dots in two-dimensional van der Waals materials, or a combination thereof.

Example 3 can include or use, or can optionally be combined with the subject matter of at least one of Examples 1-2, to include or use, wherein the atom-like system includes a quantum dot molecule, and a quantum tunneling event takes place in the quantum dot molecule.

Example 4 can include or use, or can optionally be combined with the subject matter of at least one of Examples 1-3, to include or use, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance.

Example 5 can include or use, or can optionally be combined with the subject matter of at least one of Examples 1-4, to include or use, wherein the first electric field is set to a value at which a plot of electric field dispersed eigen energy of the atom-like system versus the first electric field includes a localized substantially horizontal line about the value.

Example 6 can include or use, or can optionally be combined with the subject matter of at least one of Examples 1-5, to include or use, wherein the device is a quantum sensor, a quantum strain gauge, or a quantum information processor.

Example 7 can include or use, or can optionally be combined with the subject matter of at least one of Examples 1-6, to include or use a field effect structure, and wherein the atom-like system and the atom-like structure are embedded in the field effect structure.

Example 8 can include or use, or can optionally be combined with the subject matter of Example 7, to include or use, wherein the field effect structure includes diamond, a semiconductor, an oxide, or a combination thereof.

Example 9 can include or use subject matter (such as an apparatus including a processor configured to perform acts, a method, a means for performing acts, or a device readable memory including instructions that, when performed by the device, can cause the device to perform acts), such as can include or use a field effect structure, electrical contacts situated on, or at least partially in, the field effect structure, an electrical field generator electrically coupled between the electrical contacts, an atom-like system situated in the field effect structure and situated to interact with a first electrical field provided through the electrical contacts and produce a second electrical field responsive to the first electrical field, and an atom-like structure situated in the field effect structure and situated to interact with the first electrical field and the second electrical field, such that the atom-like structure is less sensitive to charge noise in the device.

Example 10 can include or use, or can optionally be combined with the subject matter of Examples 9, to include or use, wherein the atom-like system includes a quantum dot molecule, nitrogen vacancy centers in diamond, silicon atom dangling bond single atom quantum dots, strain-induced quantum dots in two-dimensional van der Waals materials, or a combination thereof.

Example 11 can include or use, or can optionally be combined with the subject matter of at least one of Examples 9-10, to include or use, wherein the atom-like system includes a quantum dot molecule, and a quantum tunneling event takes place in the quantum dot molecule.

Example 12 can include or use, or can optionally be combined with the subject matter of at least one of Examples 9-11, to include or use, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance.

Example 13 can include or use, or can optionally be combined with the subject matter of at least one of Examples 9-12, to include or use, wherein the first electric field is set to a value at which a plot of electric field dispersed eigen energy of the atom-like system versus the first electric field includes a localized substantially horizontal line about the value.

Example 14 can include or use, or can optionally be combined with the subject matter of at least one of Examples 9-13, to include or use, wherein the device is a quantum sensor, a quantum strain gauge, or a quantum information processor.

Example 15 can include or use, or can optionally be combined with the subject matter of at least one of Examples 9-14, to include or use, wherein the field effect structure includes diamond, a semiconductor, an oxide, or a combination thereof.

Example 16 can include or use subject matter (such as an apparatus including a processor configured to perform acts, a method, a means for performing acts, or a device readable memory including instructions that, when performed by the device, can cause the device to perform acts), such as can include or use assembling an atom-like system and an atom-like structure in a field effect structure, situating electrical contacts on the field effect structure, the atom-like system situated to interact with a first electrical field provided through the electrical contacts and produce a second electrical field responsive to the first electrical field and the atom-like structure situated to interact with the first electrical field and the second electrical field, such that the atom-like structure is less sensitive to charge noise in the device.

Example 17 can include or use, or can optionally be combined with the subject matter of Example 16, to include or use, wherein the atom-like system includes a quantum dot molecule, nitrogen vacancy centers in diamond, silicon atom dangling bond single atom quantum dots, strain-induced quantum dots in two-dimensional van der Waals materials, or a combination thereof.

Example 18 can include or use, or can optionally be combined with the subject matter of at least one of Examples 16-17, to include or use, wherein the atom-like system includes a quantum dot molecule, and a quantum tunneling event takes place in the quantum dot molecule.

Example 19 can include or use, or can optionally be combined with the subject matter of at least one of Examples 16-18, to include or use, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance.

Example 20 can include or use, or can optionally be combined with the subject matter of at least one of Examples 16-19, to include or use, wherein the first electric field is set to a value at which a plot of electric field dispersed eigen energy of the atom-like system versus the first electric field includes a localized substantially horizontal line about the value.

Although an overview of the subject matter has been described with reference to specific embodiments, various modifications and changes may be made to these embodiments without departing from the broader scope of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Moreover, plural instances may be provided for resources, operations, or structures described herein as a single instance. Additionally, boundaries between various resources, items with reference numbers, or operations, are somewhat arbitrary, and particular operations are illustrated in a context of specific illustrative configurations. Other allocations of functionality are envisioned and may fall within a scope of various embodiments of the present invention. In general, structures and functionality presented as separate resources in the example configurations may be implemented as a combined structure or resource. Similarly, structures and functionality presented as a single resource may be implemented as separate resources.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, the terms “first,” “second,” and “third,” etc. are used merely as labels, and are not intended to impose numerical requirements on their objects.

As used herein, a “-” (dash) used when referring to a reference number means “or”, in the non-exclusive sense discussed in the previous paragraph, of all elements within the range indicated by the dash. For example, 103A-B means a nonexclusive “or” of the elements in the range {103A, 103B}, such that 103A-103B includes “103A but not 103B”, “103B but not 103A”, and “103A and 103B”.

These and other variations, modifications, additions, and improvements fall within a scope of the inventive subject matter as represented by the appended claims. The specification and drawings are, accordingly, to be regarded in an illustrative rather than a restrictive sense.

What is claimed is:

1. A device comprising:
electrical contacts;
an atom-like system situated to interact with a first electrical field provided through the electrical contacts and produce a second electrical field responsive to the first electrical field; and
an atom-like structure situated to interact with the first electrical field and the second electrical field, such that the atom-like structure is less sensitive to charge noise in the device.

2. The device of claim 1, wherein the atom-like system includes a quantum dot molecule, nitrogen vacancy centers in diamond, silicon atom dangling bond single atom quantum dots, strain-induced quantum dots in two-dimensional van der Waals materials, or a combination thereof.

3. The device of claim 1, wherein the atom-like system includes a quantum dot molecule, and a controlled quantum tunneling event takes place in the quantum dot molecule.

4. The device of claim 1, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance.

5. The device of claim 1, wherein the first electric field is set to a value at which a plot of electric field dispersed eigen energy of the atom-like system versus the first electric field includes a localized substantially horizontal line about the value.

6. The device of claim 1, wherein the device is a quantum sensor, a quantum emitter, a quantum strain gauge, or a quantum information processor.

7. The device of claim 1, further comprising:
a field effect structure; and
wherein the atom-like system and the atom-like structure are embedded in the field effect structure.

8. The device of claim 7, wherein the field effect structure includes diamond, a semiconductor, an oxide, or a combination thereof.

9. A charge control system comprising:
a field effect structure;
electrical contacts situated on, or at least partially in, the field effect structure;
an electrical field generator electrically coupled between the electrical contacts;
an atom-like system situated in the field effect structure and situated to interact with a first electrical field provided through the electrical contacts and produce a second electrical field responsive to the first electrical field; and
an atom-like structure situated in the field effect structure and situated to interact with the first electrical field and the second electrical field, such that the atom-like structure is less sensitive to charge noise in the device.

10. The system of claim 9, wherein the atom-like system includes a quantum dot molecule, nitrogen vacancy centers in diamond, silicon atom dangling bond single atom quantum dots, strain-induced quantum dots in two-dimensional van der Waals materials, or a combination thereof.

11. The system of claim 9, wherein the atom-like system includes a quantum dot molecule, and a controlled quantum tunneling event takes place in the quantum dot molecule.

12. The system of claim 9, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance.

13. The system of claim 9, wherein the first electric field is set to a value at which a plot of electric field dispersed eigen energy of the atom-like system versus the first electric field includes a localized substantially horizontal line about the value.

14. The system of claim 9, wherein the device is a quantum sensor, a quantum emitter, a quantum strain gauge, or a quantum information processor.

15. The system of claim 9, wherein the field effect structure includes diamond, a semiconductor, an oxide, or a combination thereof.

16. A method of making a device with reduced comprising:
assembling an atom-like system and an atom-like structure in a field effect structure;
situating electrical contacts on the field effect structure, the atom-like system situated to interact with a first electrical field provided through the electrical contacts and produce a second electrical field responsive to the first electrical field and the atom-like structure situated to interact with the first electrical field and the second electrical field, such that the atom-like structure is less sensitive to charge noise in the device.

17. The method of claim 16, wherein the atom-like system includes a quantum dot molecule, nitrogen vacancy centers in diamond, silicon atom dangling bond single atom quantum dots, strain-induced quantum dots in two-dimensional van der Waals materials, or a combination thereof.

18. The method of claim 16, wherein the atom-like system includes a quantum dot molecule, and a controlled quantum tunneling event takes place in the quantum dot molecule.

19. The method of claim 16, wherein the atom-like system and the atom-like structure are separated by a linear distance at which a plot of electric field dispersed eigen energy of the atom-like system versus the applied electric field includes a localized substantially horizontal line around the field at which the atom-like structure exhibits a tunnel resonance.

20. The device of claim 16, wherein the first electric field is set to a value at which a plot of electric field dispersed eigen energy of the atom-like system versus the first electric field includes a localized substantially horizontal line about the value.
